(19) United States
(12) Patent Application Publication
(10) Pub. No.: US 2015/0346273 A1
(43) Pub. Date: Dec. 3, 2015

(54) BRANCH CIRCUIT MONITORING SYSTEM

(71) Applicant: Canara, Inc., San Rafael, CA (US)

(72) Inventors: Stephen D. Cotton, San Rafael, CA (US); Brian Hanking, Novato, CA (US); Jason W. Toomey, San Rafael, CA (US); Michael Carmel, Petaluma, CA (US); Douglas Sheppard, San Francisco, CA (US); Matthew James Wind, San Rafael, CA (US); Tony Yu, San Francisco, CA (US)

(73) Assignee: Canara, Inc., San Rafael, CA (US)

(21) Appl. No.: 14/726,094

(22) Filed: May 29, 2015

Related U.S. Application Data
(60) Provisional application No. 62/004,392, filed on May 29, 2014.

(51) Int. Cl. G01R 31/28; G01R 1/20

(52) U.S. Cl. CPC G01R 31/2834; G01R 1/20

(57) ABSTRACT

The present disclosure provides a branch circuit monitoring (BCM) system that may include a first collector board with a first plurality of connector ports connected to a first plurality of branch circuits, and a second collector board with a second plurality of connector ports connected to a second plurality of branch circuits. Each of the first and second plurality of connector ports may receive a respective first and second plurality of connector plugs configured to be receivable in the respective first and second plurality connector ports. The first collector board may be coupled to an aggregator board such that the first plurality of current sensors may report branch circuit measurements to the aggregator board. The plugs may be connected to associated leads connected to respective first plurality and second plurality of current sensors. The first board and the second board may be in communication using a bus protocol.

### CROSS-REFERENCE TO RELATED APPLICATION

The application claims priority to U.S. Provisional Patent Application No. 62/004,392 entitled “Branch Circuit Monitor”, filed on May 29, 2014, which is incorporated herein by reference in its entirety.

### TECHNICAL FIELD

Aspects of the present disclosure involve a branch circuit monitor system. More particularly, embodiments relate to a split core design of a branch circuit monitoring (BCM) system such that current transformers may be split into subgroups that are connected to separate collector boards or circuit boards.

### BACKGROUND

A conventional junction box, also referred to as a “panel”, generally includes 21 or 42 branch circuits on each side of a junction box for a total of 42 or 84 total circuits. Branch circuit monitors have been developed where each circuit may be monitored for current and voltage at the individual circuits. In many instances, conventional monitors involve a single large and sometimes fragile unit that spans the length of 21 circuits of a conventional panel. Such conventional branch circuit monitors, are often difficult and time consuming to install due to the dense wiring and small tight spaces of many junction boxes, and may be damaged during installation.

There remains a need for developing a BCM system which is more user-friendly.

### BRIEF SUMMARY

The present disclosure provides a BCM system that includes split collector boards that are coupled to current sensors, such as current transformers.

In an embodiment, a branch circuit monitoring (BCM) system may include a first collector board with a first plurality of connector ports connected to a first plurality of branch circuits. The first plurality of connector ports may receive a respective first plurality of connector plugs configured to be receivable in the respective first plurality connector ports. The plugs may be connected to associated leads connected to a respective first plurality of current sensors. The first collector board may be coupled to an aggregator board such that the first plurality of current sensors may report branch circuit measurements to the aggregator board. The BCM system may also include a second collector board with a second plurality of connector ports connected to a second plurality of branch circuits. The second plurality of connector ports may receive a respective second plurality of connector plugs configured to be receivable in the respective second plurality of connector ports. The plugs may be connected to associated leads connected to a respective second plurality of current sensors. The first board and the second board may be in communication using a bus protocol such that the second plurality of current sensors may report branch circuit measurements to the aggregator board.

In an embodiment, a BCM system may include a first collector board with a first plurality of connector ports connected to a first plurality of branch circuits. The first plurality of connector ports may receive a respective first plurality of connector plugs configured to be receivable in the respective first plurality connector ports. The plugs may be connected to associated leads connected to a respective first plurality of current sensors. The first collector board may be coupled to an aggregator board such that the first plurality of current sensors may report branch circuit measurements to the aggregator board. The BCM system may also include a second collector board with a second plurality of connector ports connected to a second plurality of branch circuits. The second plurality of connector ports may receive a respective second plurality of connector plugs configured to be receivable in the respective second plurality of connector ports. The plugs may be connected to associated leads connected to a respective second plurality of current sensors. The first board and the second board may be in communication using a bus protocol such that the second plurality of current sensors may report branch circuit measurements to the aggregator board. The BCM system may also include at least the first collector board comprises an orientation sensor configured to automatically determine orientation of the first collector board and to automatically number the first plurality and second plurality of branch circuits depending on the orientation of the collector boards.

In an embodiment, a method for monitoring branch circuits in a processor is provided. The method may include receiving a signal from an orientation sensor in a first collector board having a first plurality of current transformers operably connected to a first plurality of branch circuits. The method may also include determining an orientation of the first collector board according to the orientation sensor. The method may further include receiving current or voltage measurements from the first plurality of current transformers. The method may also include determining if there is a secondary collector board coupled to a second plurality of current transformers connected to a second plurality of branch circuits, followed by automatically sequentially numbering the first plurality and second plurality of branch circuits if the secondary collector board is present or automatically sequentially numbering the first plurality of branch circuits if the secondary collector board is not present, and reporting current or voltage measurements of the first plurality and second plurality of branch circuits.

Additional embodiments and features are set forth in part in the description that follows, and will become apparent to those skilled in the art upon examination of the specification or may be learned by the practice of the disclosed subject matter. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as various embodiments of the disclosure and should not be construed as a complete recitation of the scope of the disclosure, wherein:

FIG. 1 is an electrical schematic illustrating a system with one aggregator and four sets of two collector boards in accordance with one embodiment of the present disclosure.

FIG. 2 is an electrical schematic illustrating a system with one aggregator and four sets of three collector boards in accordance with another embodiment of the present disclosure.

FIG. 3 is an example system diagram illustrating a plurality of BCM collector boards coupled with a BCM aggregator board and configured to use a controller area network (CAN) and Ethernet to provide information to and from the respective components including reporting of BCM measurements.

FIG. 4 shows a diagram illustrating a 42 circuit panel with modular collectors and associated current transformers coupled to circuits in accordance with embodiments of the present disclosure.

### DETAILED DESCRIPTION

Aspects of the present disclosure involve a branch circuit monitoring (BCM) system. The BCM system delivers circuit-level electrical usage information by using current transformers to detect current or voltage from branch circuits in a junction box. The BCM includes modular collector boards, which may be deployed in a master/slave arrangement with current transformers connected to the collector boards with leads, which alone or in combination, facilitates installation, reliability, and/or extendability among other benefits of the BCM. By monitoring electrical power at circuit levels, load-based cost allocation may be enabled. Capacity planning may be improved. The BCM system may also provide timely reporting of anomalies and present electrical usage history.

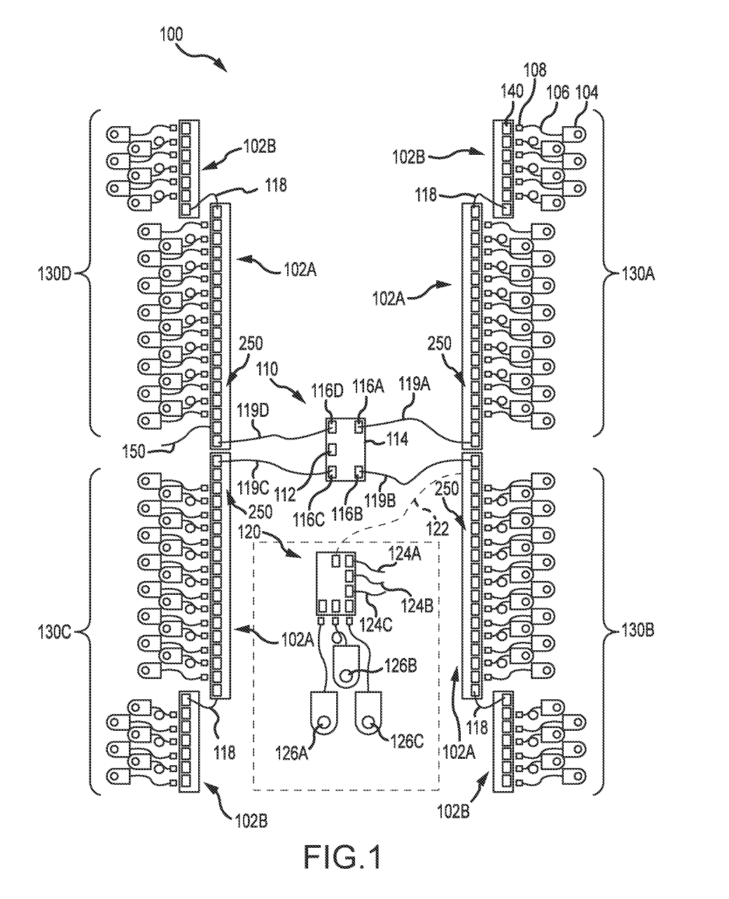

FIG. 1 is an electrical schematic illustrating a system with one aggregator and four sets of collector boards in accordance with one embodiment of the present disclosure. The four sets of collector boards provide 84 total possible monitored circuits and hence, in the combination shown, could be deployed in an 84 circuit panel. As shown in the system illustrated, a branch circuit monitor system 100 may be deployed to monitor circuits that include circuit breakers for controlling electrical power to the circuits, Four sets 130A-D of collector boards are electrically coupled to respective connector ports 116A-D of an aggregator board 110, directly or indirectly. The collector boards include connector ports and circuits configured to report current and voltage measurements of the current transformers for each monitored circuit to the aggregator board. The collector boards also include communication means, such as a bus protocol between them so that collector boards may be deployed in a master/slave arrangement and the current/voltage measurement electronics may be split across modular collector board assemblies to ease installation. The aggregator board 110 may include an Ethernet port such that the aggregator board is in communication with a data center to report the branch circuit measurements from the collector boards.

Each of the four sets 130A-D of collector boards may include a first collector board 102A in direct communication with the aggregator 110, such that the first collector board can report branch circuit measurements to the aggregator 110. A second collector board 102B may be in indirect communication with the aggregator 110 through the first collector board using a communication means 118, such as a bus protocol. By using the communication means 118, the second collector board can report branch circuit measurements to the aggregator board. The first collector board may also be referred to a master board or a primary board, while the second collector board may be referred to a secondary board or slave board.

The first collector board 102A may include six connector ports 140, which may facilitate electrical connections to 6 plug-in split core current transformers (CTs) 104. The current transformers 104 may be configured to measure current on six respective branch circuits through the six connector ports 140. The split-core current transformers provide linear output voltage that is directly proportional to the input current. These transformers can be safely and easily installed over existing electrical power lines without disconnecting lines or interrupting service. While multiple sets of collector boards are illustrated, the collector boards may be used in various possible combinations ranging from a single collector board to enough collector boards for fully monitoring all active circuits in a junction box.

The second collector board 102B may be a secondary collector board, including fifteen connector ports 140, which may facilitate fifteen split core plug-in current transformers 104. In combination with the master collector board, 21 circuits may be measured when also using the secondary collector boards in some panels, there are 21 circuits on each side and these master and slave collector boards may be deployed to measure the circuits on each side.

The first and second collector boards 102A-B may collectively provide for up to twenty-one connector ports 140 to receive respective twenty-one current detectors 104. In the present example, the current detectors are in the form of a split core current transformer that may be connected to monitor a respective branch circuit (not shown). A current transformer 104 is connected to a plug 108 by using a relatively short lead 106 so that the collector boards 102A-B may be positioned relatively close to the respective branch circuit. The leads may provide adjustability in placement of the current transformers and boards to the circuit wires and within the confined space of the junction box. In one specific example, the leads 106 may be about 4 inches to 8 inches long. The plugs 108 may be configured to be receivable in connection ports 140.

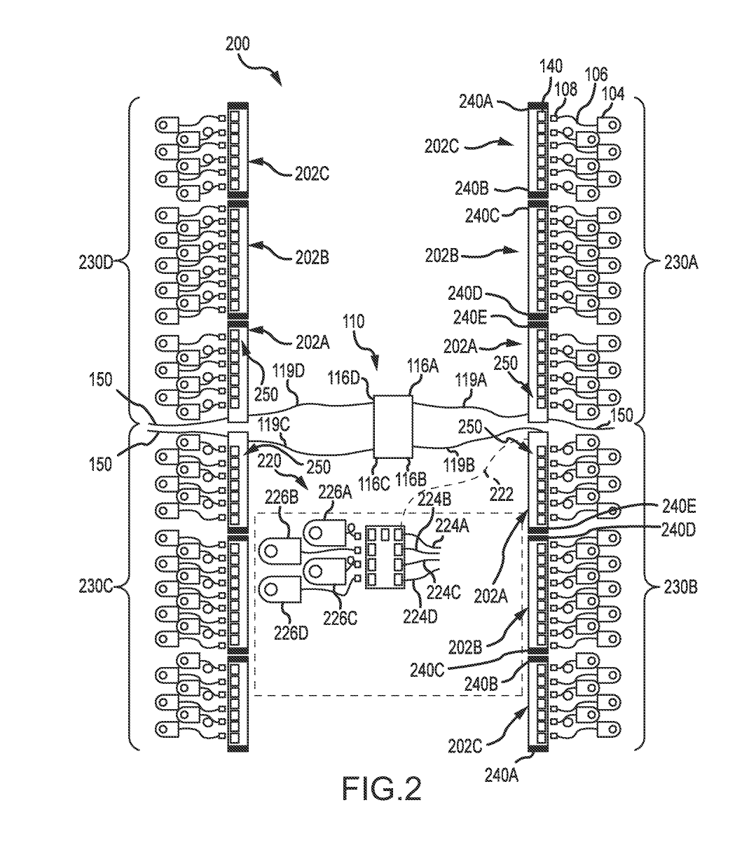

FIG. 2 is an electrical schematic illustrating a system with one aggregator board and four sets of collector boards in accordance with another embodiment of the present disclosure. In this example, 21 currents may be monitored through a combination of three collector boards as opposed to the two collector boards illustrated in FIG. 1. As shown, a branch circuit monitor system 200 may include four sets 230A-D of collector boards. Each of sets 230A-D of the collector boards may include a first or primary or master collector board 202A that is in direct communication with aggregator board 110, and a second collector board 202B configured to be connected to the first collector board 202A. The second collector board is in indirect communication with the aggregator board 110 through the first collector board 202B using a connector 218 including a male portion and a female portion. Similarly, a third collector board 202C is configured to be connected to the second collector board 202B or the first collector board 202A such that the third collector board is in indirect communication with the aggregator board 110 through the first collector board 202B using a connector 218 including a male portion and a female portion.

The first collector board 202A may include six connector ports 140 to provide electrical connections to respective six plug-in split current transformers 104. The current transformers 104 may be configured to measure current or voltage on six respective branch circuits.

The second collector board 202B may be optional or secondary, including nine connector ports 140, which may facilitate nine split core plug-in current transformers 104. The third collector board 202C may also be optional or secondary, including six collector ports 140 that are connected to six branch circuit boards (not shown).

The collector boards may be deployed in various combinations depending on the number and arrangement of circuits to be monitored. For example, in some cases, a junction box may include six or fewer active branch circuits that may require six CTs provided by only primary collector board 102A or 202A. In some cases, a junction box may include between 7 and 12 circuits and thereby require twelve CTs provided by the primary collector board 202A with six collector ports 140 and the secondary collector board 202C also with six collector ports 140, but does not require a second secondary collector board 202B including nine connector ports. In some cases, a junction box may include fifteen active branch circuits that may require fifteen CTs provided by one master collector board 202A and one slave or secondary collector board 202B. In some cases, a junction box may include between 16 and 21 active circuits and thereby may require twenty-one CTs provided by one master collector board 202A, a first slave collector board 202C and a second slave collector board 202B for ease of installation. Thus, as more circuits are added to a panel, the BCM may be expanded to accommodate such additions. As discussed below, new circuits and collectors are automatically recognized further easing expanding of the BCM and installation.

To monitor the branch circuits, split core current transformers attached to the collector boards via leads may be attached to wires extending from respective circuits. Then, leads of the current transformers may be plugged into the sockets of the collector boards. Alternatively, the current transformers may be first plugged into the collector boards and then operatively coupled to respective circuits. The secondary collector board may be connected to the master board. The master board may also be connected to the aggregator board. These collector and aggregator boards may be positioned inside or possibly outside the junction box depending on the CT lead lengths and other factors.

The primary or master collector board may include a connection to the aggregator board and connections to the secondary boards, so that the BCM measurements from the secondary collector board(s) may be transmitted to the aggregator board through the connection to the primary board. In some cases, the slave collector boards may be electrically connected to the master collector board by connectors such that the slave collector board can report current and/or voltage measurements to the aggregator board through the master collector board. The first and second collector boards 202A-B may be connected or plugged into each other through connectors 240E and 240D. Referring to collector board 202A now, the collector board 202A includes a connector 240E on the top which is configured to connect to a connector 240D at the bottom of the secondary collector board 202B. The secondary collector board 202B includes a top connector 240C configured to connect to a bottom connector 240B of the slave collector board 202C. The third collector board 202C may be connected the second collector board 202B through connectors 240B and 240C or into first collector board 202A through connectors 240E and 240B.

In the specific examples illustrated in FIG. 1 or FIG. 2, the master or primary collector board 102A or 202A includes six connector ports for respective six current transformers 104. The secondary collector board may include 6 or 9 or 15 or a combination with connector ports for a total of up to 21 current transformers. It will be appreciated by those skilled in the art that the number of plug-in current transformers may vary, for example, may involve other numbers, more or less than 6 or 15, and the number of boards may also be larger than two or three. In one example, each of the current transformers 104 communicates with the aggregator board 110 using a controller area network bus (CANbus) protocol 118. Accordingly, the connection between the collector boards 102A-B or 202A-C may communicate using the CANbus protocol. Similarly, the secondary board may include a second CANbus port, where the aggregate 21 current transformers may provide current information from the respective branch circuits to the aggregator board 110.

The master board 102A or 202A, may include a processor (not shown) to convert readings from the current transformers 104 into suitable CANbus format for communication to the aggregator board 110.

The aggregator board 110 may include an Ethernet port 112 so that an Ethernet connection may be made to various possible network components in order to receive data from the current transformers 104 as well as communication with computing elements that may be on one or both collector boards. The aggregator board may include a DC power supply 114. The DC power supply 114 may also be provided to the respective sets 130A-D or 230A-D of collector boards through connections 116A-D or 216A-D. In alternative embodiments, the DC power may be replaced by PoE Splitter and PoE Switch, which provide power through Ethernet.

The present system, such as shown in FIG. 1 or FIG. 2, may be configured to be installed with a new junction box. The present BCM system may also to be retrofitted to an existing box. In the case of an existing junction box, providing the current transformers 104 with leads 106 and splitting the current transformers 104 across at least two or more collector boards. The present BCM system may provide additional flexibility for various combinations of collector boards such that the number of current performers may vary. The present BCM system may also be easy for installation due to split core current transformers without shutting off or disconnecting the power of the branch circuits. The installation of the BCM may be easier and may require less time and due to the adjustability or flexibility in placement or arrangement as provided by modularity of the collector boards, because of the split collector boards and the current transformers with leads coupled to the collector boards. The present BCM system may take much shorter time to install than the conventional design. The present BCM system may also be more robust or damage resistant when compared to, for example, a conventional design where all 21 current transformers are mounted on a single collector board.

The BCM system may be configured such that current transformers can be automatically detected and discovered, when the current transformers are plugged into one or both collector boards. In some embodiments, each master collector board may be sensitive to its orientation so that the BCM system can automatically number the branch circuits in sequence. For example, the branch circuits associated with the current transformers may be numbered sequentially, like 1,2,3,4 etc. The branch circuits may also be numbered in odd or even numbers sequentially, such as 2,4,6,8 etc. and/or 1,3,5,7 etc., regardless of orientations of the collector boards. This automatic numbering of branch circuits allows to view and report voltage or current usage of each branch circuit by using a software package.

In some embodiments, the BCM system may include an orientation sensor 250 on the master collector board or other board(s). This orientation sensor 250 may automatically detect that the primary collector board 202A is at the bottom of the set 230A of collector boards, while the primary board of set 230B is detected to be at the top of the set 230B of collector boards. This automatic detection of orientation of the primary collector board helps automatically numbers each circuit as described below.

As current transformers 104 are connected to the collector boards, the BCM system can automatically discover the connection to the current transformers, assigns each current transformer an address, a location, and a circuit number (e.g. 1, 3, 5, . . . or 2, 4, 6 . . . ). Referring to FIG. 2 again, for the first set 230A with the master collector board 202A on the bottom and the secondary collector boards 202B or 202C above the master collector board 202A. In this case, the orientation sensor 250 may indicate that connector 240E is positioned at the top of the master collector board 202A, such that the connector 240E of the master collector board 202A can connect to connector 240D or 240B at the bottom of the respective secondary collector board 202B or 202C. The current or voltage measurements may be reported to the aggregator board from slave collector board 202B through connectors 240D-E or from slave collector board 202C through connectors 240B-C. Therefore the circuit associated with the top current transformer of secondary collector board 202C may be numbered as a starting number 1 and the rest of the circuits associated with current transformers of slave collector board 202C may be sequentially numbered as 3, 5, 7, 9, and 11, the circuits associated with current transformers of the slave collector board 202B may be sequentially numbered as 13, 15, 17, . . . 29 while the circuits associated with current transformers of master collector board 202A may be numbered sequentially as 31, 33, . . . 41. Similarly, on the opposing side of the panel, circuits may be auto-numbered 2, 4, 6 . . . For the slave boards and the master board.

Likewise, for the second set 230B with the primary collector board 202A on the top and the secondary collector board 202B or 202C under the primary board 202A, if an orientation sensor indicates that the master collector board is oriented such that connector 240E is positioned at the bottom of the master collector board 202A, i.e. the master collector board is on top of the slave collector board 202B, the top current transformer of master collector board 202A may be numbered as 1, and the bottom current transformer of the master collector board 202A may be sequentially numbered as 11 while the current transformers of slave collector board 202C may be sequentially numbered as 13, 15, 16, . . . , 29, the current transformers of slave collector board 202C may be sequentially numbered as 31, 33, . . . , 41.

As explained above, the BCM system can then recognize the existence of the current transformers and is able to begin receiving current measurements. Thus, the BCM system is flexible and may be usable in situations where not all 21 branch circuits are utilized, or when some branch circuits are aggregated across larger sized panels.

In some embodiments, the current transformers may output voltage. A burden resistor may be provided within the current transformer to convert an electric current measurement to a voltage measurement, which may be proportional to the electric current. The voltage measurement may be reported to monitoring operation center through Ethernet port 212. The burden resistor may be mounted inside the current transformer, which may allow for safe connection of the current transformer to cables. The system may be mounted without necessarily having to disconnect or interrupt power.

In some embodiments, the BCM system may include power board 220, which may be sensitive to its orientation. The BCM system can automatically number the main phase circuits and neutral in sequence despite being mounted in a number of different orientations.

Referring to FIG. 1 again, the power board 120 may be connected to at least one of the master boards 102A through connection 122. The power board may include ports 124A-C for three phases AC voltage. The power board 120 may also include current transformers 126A-C for three AC phases.

Referring to FIG. 2 again, the power board 220 may be connected to at least one of the master boards 202A through connection 222. The power board 220 may be used to measure and report the three phases of the AC voltage received in the panel or junction box. The three phase AC voltage received in the junction box may be 240 Volts. On each side of the panel, the AC voltage may be half of the total AC voltage. The three phases AC voltage may be measured by at least three current transformers and may be four current transformers. The power board may include ports 224A-D for three phases AC voltage, and neutral connections. The power board 220 may also include current transformers 226A-D for three AC phases and neutral or ground.

In some embodiments, the BCM system may include expansion line connected to the master collector boards 102A or 202A, which allow to expand to other collector boards.

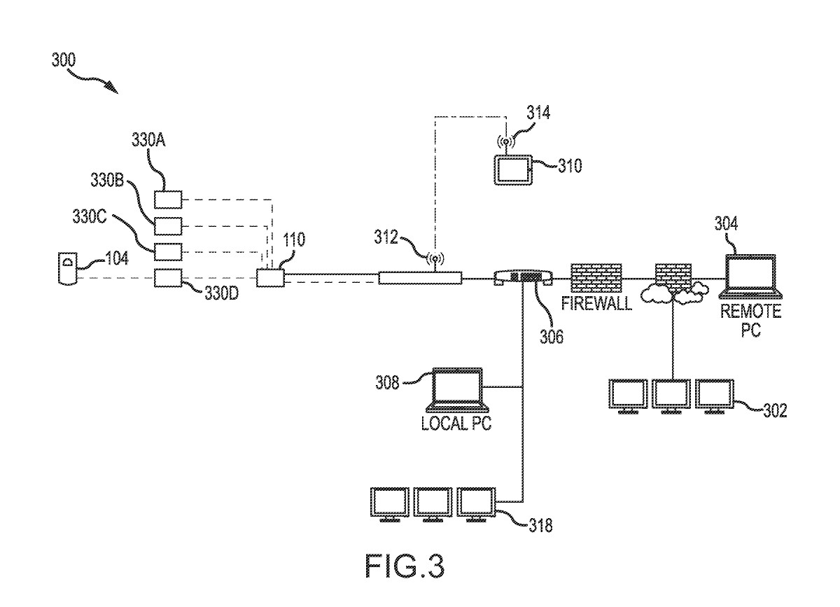

FIG. 3 is a monitoring system diagram illustrating a plurality of BCM collectors coupled with a BCM aggregator board and configured to use a controller area network (CAN) and Ethernet to provide information to and from the respective components including reporting of BCM measurements. As shown, monitoring system 300 may include current transducers, such as current transformers 104 connected to BCM collector boards 130A-D or 230A-D, which are electrically coupled to aggregator board 110 or 210.

The monitoring system 300 may include a monitoring operation center 302 or a PC 304 that is remotely connected to the aggregator 110 through Ethernet router 306. This monitoring operation center 302 or a PC 304 may remotely monitor the outputs from the current transducers 104. The monitoring center may provide monitoring services to users by providing secure, authenticated access to branch circuit system usage metrics.

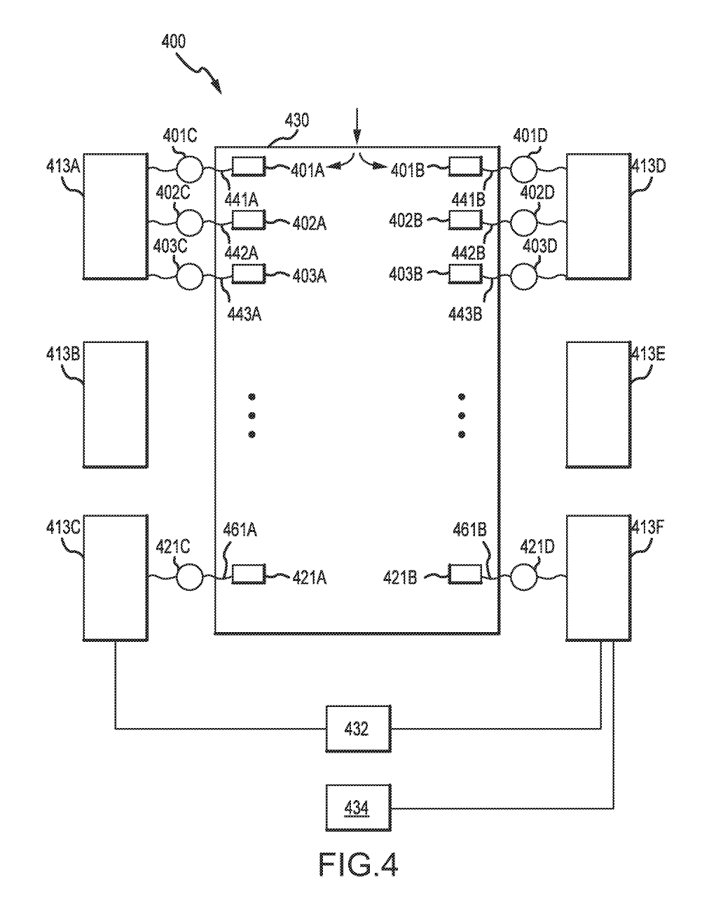

A conventional junction box may be fitted or retrofitted to include a BCM as discussed here. FIG. 4 shows a diagram illustrating a junction box with a BCM system including the current transformers coupled to 21 circuits on each side in accordance with embodiments of the present disclosure. As shown, a panel 400 may include a housing 430 providing power to 21 circuit wires 401A-421A on a left side, and 401B-421B on a right side inside the housing 430. The retrofitted junction box 400 may also include 21 current transformers 401C-421C that are electrically coupled to the circuit wires 401A-421A on the left side, and 21 current transformers 401D-421D that are electrically coupled to the circuit wires 401B-421B. These current transformers are electrically coupled to respective collector boards 431A-C on the left side through leads 441A-461A, and respective collector boards 431D-F on the right side through leads 441B-461B. The collector boards 431A-C or 431D-F may 6, 9, and 6 connector ports, respectively, which are easy for installation. The master collector boards on each of left side and right side may be coupled to an aggregator board 432 for reporting currents or voltages of branch circuits. A power board 434 may be coupled to at least one of the master boards for monitoring three phases AC input voltage to the junction box 430. All the collector boards, the aggregator board and the power board may be placed inside or outside the junction box 430.

The present BCM system including split collector boards and current transformers may be installed by a user in an existing junction box including 21 branch circuits on each side and may then be upgraded for remote monitoring by either a monitoring operation center 302 or a PC 304 for displaying GUI with circuit information. This upgrade may be enabled by automatic detection of current transformers and automatic discovery of the orientation of the master collector board and automatic numbering of the current transformers coupled to branch circuits.

The present BCM system may be used in data centers. As data centers consume vast amounts of energy. There is a need to understand energy usage for various tenants, such as for billing precision and potential points of energy waste.

One of the benefits of the branch circuit monitoring may include providing capacity planning metrics to building management system 318. The benefits may also include detecting imminent circuit-level threshold violations early, preventing tripped circuits, mitigating risk of downtime as a result of over-current scenarios, identifying phase or load imbalance at the panel level, allowing for reclamation of stranded power, enabling usage-based billing, adding load safety and preemptively identify need for additional capacity by tenant, and providing clients with automatic or online capacity reports.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

We claim:

1. A branch circuit monitoring system comprising:
a first collector board with a first plurality of connector ports connected to a first plurality of branch circuits, the first plurality of connector ports receiving a respective first plurality of connector plugs configured to be receivable in the respective first plurality connector ports, the plugs being connected to associated leads connected to a respective first plurality of current sensors, the first collector board being coupled to an aggregator board such that the first plurality of current sensors may report branch circuit measurements to the aggregator board; and
a second collector board with a second plurality of connector ports connected to a second plurality of branch circuits, the second plurality of connector ports receiving a respective second plurality of connector plugs configured to be receivable in the respective second plurality of connector ports, the plugs being connected to associated leads connected to a respective second plurality of current sensors;
the first board and the second board in communication using a bus protocol such that the second plurality of current sensors may report branch circuit measurements to the aggregator board.

2. The system of claim 1, wherein the first collector board comprises 6 connector ports.

3. The system of claim 2, wherein the second collector board comprises 6, 9 or 15 connector ports.

4. The system of claim 3, wherein the system comprises one of 6 collector ports, 12 collector ports, 15 collector ports, or 21 collector ports.

5. The system of claim 1, wherein the system is configured to allow for sequential numbering, odd numbering, or even numbering of the first plurality and second plurality of connector ports that are connected to respective branch circuits.

6. The system of claim 1, wherein the current sensors comprise split core current transformers.

7. The system of claim 1, wherein the bus protocol comprises a controller area network protocol.

8. The system of claim 1, wherein the first collector board comprises an orientation sensor configured to automatically determine orientation of the first collector board and to automatically number the first plurality and second plurality of branch circuits depending on the orientation of the collector boards.

9. The system of claim 1, wherein the aggregator board comprises an Ethernet port.

10. The system of claim 1, wherein at least one of the first collector boards comprises a connection to a power board that comprises three ports for three AC phases of an AC voltage signal and a port for neutral or ground, wherein the power board comprises respective ports receivable to current sensors for three AC phases and for neutral or ground.

11. The system of claim 1, further comprising
a third collector board with a third plurality of connector ports, the third plurality of connector ports receiving a respective third plurality of connector plugs receivable in the respective connector ports, the plugs being connected to associated leads connected to a respective second plurality of current sensors;
the third collector board in communication with the first board using the bus protocol such that the third plurality of current sensors can report branch circuit measurements to the aggregator board.

12. The system of claim 1, wherein the third collector board comprises 6 connector ports.

13. A branch circuit monitoring system comprising:
a first collector board with a first plurality of connector ports connected to a first plurality of branch circuits, the first plurality of connector ports receiving a respective first plurality of connector plugs configured to be receivable in the respective first plurality connector ports, the plugs being connected to associated leads connected to a respective first plurality of current sensors, the first collector board being coupled to an aggregator board such that the first plurality of current sensors may report branch circuit measurements to the aggregator board; and
a second collector board with a second plurality of connector ports connected to a second plurality of branch circuits, the second plurality of connector ports receiving a respective second plurality of connector plugs configured to be receivable in the respective second plurality of connector ports, the plugs being connected to associated leads connected to a respective second plurality of current sensors;
wherein the first board and the second board are in communication using a bus protocol such that the second plurality of current sensors may report branch circuit measurements to the aggregator board; and
at least the first collector board comprises an orientation sensor configured to automatically determine orientation of the first collector board and to automatically number the first plurality and second plurality of branch circuits depending on the orientation of the collector boards.

14. A method for monitoring branch circuits in a processor, the method comprising:
receiving a signal from an orientation sensor in a first collector board having a first plurality of current transformers operably connected to a first plurality of branch circuits;
determining an orientation of the first collector board according to the orientation sensor;
receiving current or voltage measurements from the first plurality of current transformers;
determining if there is a secondary collector board coupled to a second plurality of current transformers connected to a second plurality of branch circuits;
automatically sequentially numbering the first plurality and second plurality of branch circuits if the secondary collector board is present or automatically sequentially numbering the first plurality of branch circuits if the secondary collector board is not present; and
reporting current or voltage measurements of the first plurality and second plurality of branch circuits.

15. The method of claim 14, wherein the current transformers comprise split core current transformers.

16. The method of claim 14, wherein the current transformers comprise respective burden resistors to convert an electric current measurement to a voltage measurement.

17. The method of claim 14, wherein reporting current or voltage measurements of the branch circuits comprises reporting the current or voltage measurements through an Ethernet to a remote personal computer or a remote data center.

18. The method of claim 14, wherein reporting current or voltage measurements of the branch circuits comprises displaying the current or voltage measurements on a local personal computer or a local data center.

19. The method of claim 14, wherein reporting current or voltage measurements of the branch circuits comprises reporting the current or voltage measurements to a wireless device.
